(19) United States
(12) Patent Application Publication
(10) Pub. No.: US 2014/0320719 A1
(43) Pub. Date: Oct. 30, 2014

(54) SOLID-STATE IMAGE DEVICE, METHOD FOR DRIVING SAME, AND CAMERA SYSTEM

(71) Applicant: Sony Corporation, Tokyo (JP)

(72) Inventors: Kiyoshige Tsuji, Kanagawa (JP); Miyuki Eguchi, Kanagawa (JP)

(21) Appl. No.: 14/355,998

(22) PCT Filed: Nov. 30, 2012
(86) PCT No.: PCT/JP2012/081052

§ 371 Date: May 2, 2014

(30) Foreign Application Priority Data
Dec. 7, 2011 (JP) 2011-267522

(51) Int. Cl. H04N 5/378; H04N 5/374

(52) U.S. Cl. CPC H04N 5/378; H04N 5/374
USPC 348/308

(57) ABSTRACT

Provided is a solid-state image device including a pixel unit adapted to have a plurality of pixels arrayed in a matrix form, the plurality of pixels including a photoelectric conversion element which converts an optical signal into an electrical signal and stores signal charge corresponding to exposure time, peripheral circuits adapted to be arranged adjacent to edge portions of the pixel unit that face each other and adapted to be driven in association with at least read operation of a pixel signal, and a pixel signal readout unit adapted to read the pixel signal from the pixel unit in a unit of a plurality of pixels.

### TECHNICAL FIELD

The present invention relates to a solid-state image device which performs full-pixel readout, a method for driving the same, and a camera system.

### BACKGROUND ART

In recent years, image sensors, though having high resolution, are required to image fine-quality images at low resolution.

For example, such functions as photographing a moving image with a digital still camera and on the contrary, imaging a static image with a camcorder are gaining popularity.

Moreover, such electronic apparatuses often have a view finder for confirming pictures, though the resolution of the view finder is usually lower than the resolution of imaged images.

Further, some of digital still cameras and mobile phones incorporate a function of increasing a frame rate at the time of imaging at low resolution so as to image high-speed movements which were conventionally unrecognizable.

As described in the foregoing, it is required to support, with only one image sensor, both a static image of a low frame rate with high resolution and a moving image of a high frame rate with relatively low resolution.

Patent Literature 1 discloses a technology which enables a charge coupled device (CCD) image sensor to obtain an output signal without a signal output load period and to meet the request for the high frame rate.

In contrast, a complementary metal oxide semiconductor (CMOS) image sensor has been proposed which supports a full-pixel mode for reading a signal from all the pixels and a thinning mode for intermittently reading a signal by skipping a row and/or a column.

In the CMOS image sensor, the full-pixel mode is used at the time of photographing a static high-resolution image, while the thinning mode is used for imaging a low-resolution moving image and/or an image of the high frame rate.

Now, a one-channel (ch) output circuit with use of a floating diffusion (FD) amplifier having an FD layer is mainly used as an output circuit of the CCDs.

Contrary to this, the CMOS image sensor has an FD amplifier in each pixel, and a column parallel output configuration is mainly used in which one row is selected from a pixel array and the pixels in the row are simultaneously read out in a column direction.

This is because parallel processing is advantageous to reduction in data rate, which is necessary since it is difficult to acquire sufficient driving power only from the FD amplifier arranged in each pixel.

A wide variety of pixel signal readout (output) circuits have been proposed for the column parallel output-type CMOS image sensor.

One of the most advanced circuits among these is of a type which includes an analog-to-digital conversion device (hereinafter abbreviated to an analog digital converter (ADC)) in each column to take out a pixel signal as a digital signal.

Here, full proofread operation in a general CMOS image sensor will be described.

FIGS. 1(A) to 2(B) are explanatory views illustrating an outline of the full-pixel readout operation in a general CMOS image sensor.

A CMOS image sensor 1 of FIG. 1 is configured to include: a pixel unit 2 in which pixels including a photoelectric conversion function are arrayed in an array configuration; pixel current sources 3D and 3U for pixel readout; and readout circuits 4D and 4U such as column ADCs.

While the pixel current sources 3D and 3U are connected to a signal line so as to form a source follower with an FD amplifier of the pixel for pixel readout, a configuration of providing them on both ends of the signal line (upper and lower sides of the pixel unit 2) is applied to secure impedance.

FIG. 1 illustrate an example in which the readout circuits 4D and 4U are arranged at the upper and lower ends of the pixel unit 2. FIG. 2 illustrate an example in which the readout circuit 4D is arranged only at one (lower end) of the upper and lower ends of the pixel unit.

When the full-pixel readout is performed, all the pixels are simultaneously reset as illustrated in FIGS. 1(A) and 2(A).

Then, readout is performed, for example, one row at a time in order from the lower end to the upper end of the pixel unit 2.

### CITATION LIST

### Patent Literature

Patent Literature 1: JP H06-217206 A

### SUMMARY OF INVENTION

### Technical Problem

However, light and heat are generated from peripheral circuits (such as pixel current source and readout circuits) during read operation.

The light and heat generated in the pixel current source 3 have a particularly large influence.

When the pixel unit 2 is read from the lower end to the upper end, the locations close to the upper end have longer charge storage time.

Since a portion (a portion encircled with a dotted line) close to the peripheral circuit at the upper end receives the influence of the light and heat generated from the peripheral circuit for a long period of time, the portion causes whitening with a shading pattern.

Moreover, as illustrated in FIG. 3, when the frame rate is reduced, the time for receiving the influence from the peripheral circuit is further extended, which makes the whitening phenomenon notable. Since the image sensor having a large number of pixels has a slow frame rate, this phenomenon causes a serious problem.

When the pixel current sources are provided on the upper and lower sides, the pixels that are read out later cause whitening due to the light and heat generated by the pixel current sources even if the readout circuit (such as column ADCs) is provided only on one side.

It is an object of the present invention to provide a solid-state image device which can suppress whitening at the end of the screen due to the influence of peripheral circuits, a method for driving the same, and a camera system.

According to a first aspect of the present invention, there is provided a solid-state image device including a pixel unit adapted to have a plurality of pixels arrayed in a matrix form, the plurality of pixels including a photoelectric conversion element which converts an optical signal into an electrical signal and stores signal charge corresponding to exposure time, peripheral circuits adapted to be arranged adjacent to edge portions of the pixel unit that face each other and adapted to be driven in association with at least read operation of a pixel signal, and a pixel signal readout unit adapted to read the pixel signal from the pixel unit in a unit of a plurality of pixels. When full-pixel readout is performed, the pixel signal readout unit resets all the pixels, and then performs pixel readout at least row by row alternately from at least rows in specific regions close to the peripheral circuits arranged beside the edge portions of the pixel unit that face each other.

According to a second aspect of the present invention, there is provided a method for driving a solid-state image device including peripheral circuits adapted to be arranged adjacent to edge portions that face each other and adapted to be driven in association with at least read operation of a pixel signal, and a pixel unit adapted to have a plurality of pixels arrayed in a matrix form, the plurality of pixels including a photoelectric conversion element which converts an optical signal into an electrical signal and stores signal charge corresponding to exposure time, the method including, when full-pixel readout is performed on the pixel unit, a resetting step of resetting all the pixels, and a readout step of performing pixel readout at least row by row alternately from at least rows in specific regions close to the peripheral circuits arranged beside the edge portions of the pixel unit that face each other.

According to a third aspect of the present invention, there is provided a camera system including a solid-state image device, and an optical system adapted to form an object image on the solid-state image device. The solid-state image device includes a pixel unit adapted to have a plurality of pixels arrayed in a matrix form, the plurality of pixels including a photoelectric conversion element which converts an optical signal into an electrical signal and stores signal charge corresponding to exposure time, peripheral circuits adapted to be arranged adjacent to edge portions of the pixel unit that face each other and adapted to be driven in association with at least read operation of a pixel signal, and a pixel signal readout unit adapted to read the pixel signal from the pixel unit in a unit of a plurality of pixels. When full-pixel readout is performed, the pixel signal readout unit resets all the pixels, and then performs pixel readout at least row by row alternately from at least rows in specific regions close to the peripheral circuits arranged beside the edge portions of the pixel unit that face each other.

### Advantageous Effects of Invention

According to the present invention, whitening at the end of the screen due to the influence of peripheral circuits can be suppressed.

### BRIEF DESCRIPTION OF DRAWINGS

FIG. 1 are first views for describing an outline of full-pixel readout operation in a general CMOS image sensor.

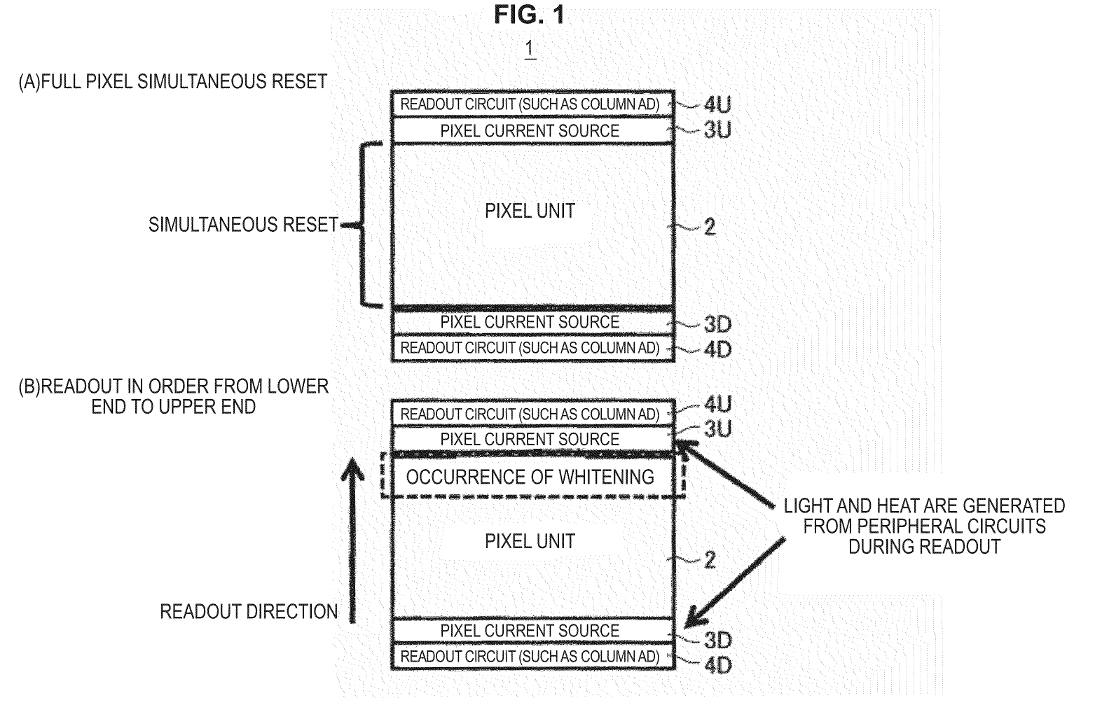

FIG. 2 are second views for describing an outline of the full-pixel readout operation in a general CMOS image sensor.

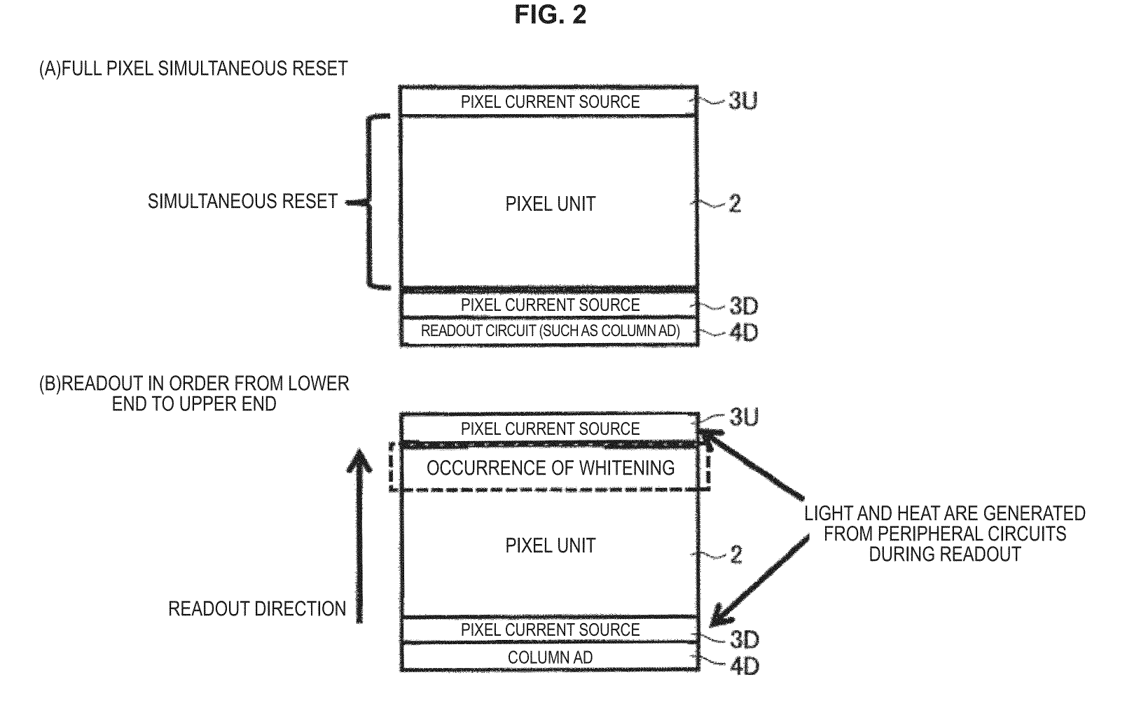

FIG. 3 are explanatory views illustrating occurrence of whitening in the general CMOS image sensor.

FIG. 4 is a block diagram illustrating a configuration example of a column parallel ADC-mounted solid-state image device (CMOS image sensor) according to a first embodiment.

FIG. 5 illustrates one example of a pixel including four transistors in the CMOS image sensor according to the embodiment.

FIG. 6 illustrates a concrete configuration example of pixel current sources arranged on both upper and lower ends of a pixel unit according to the embodiment.

FIG. 7 are explanatory views illustrating an operation example of full-pixel readout in the solid-state image device according to the present embodiment.

FIG. 8 illustrates a pixel configuration example in two-pixel sharing.

FIG. 9 illustrates a pixel configuration example in four-pixel sharing.

FIG. 10 is a block diagram illustrating a configuration example of a column parallel ADC-mounted solid-state image device (CMOS image sensor) according to a second embodiment.

FIG. 11 illustrates configuration of a pixel unit in a column parallel ADC-mounted solid-state image device (CMOS image sensor) according to a third embodiment.

FIG. 12 illustrates one configuration example of a camera system to which the solid-state image device according to the embodiment is applied.

### DESCRIPTION OF EMBODIMENTS

Hereinafter, preferred embodiments of the present invention will be described in detail with reference to the appended drawings.

The description will be given in the order shown below:

1. First embodiment (first configuration example of solid-state image device)
2. Second embodiment (second configuration example of solid-state image device)
3. Third embodiment (third configuration example of solid-state image device)
4. Fourth embodiment (configuration example of camera system)

### 1. First Embodiment

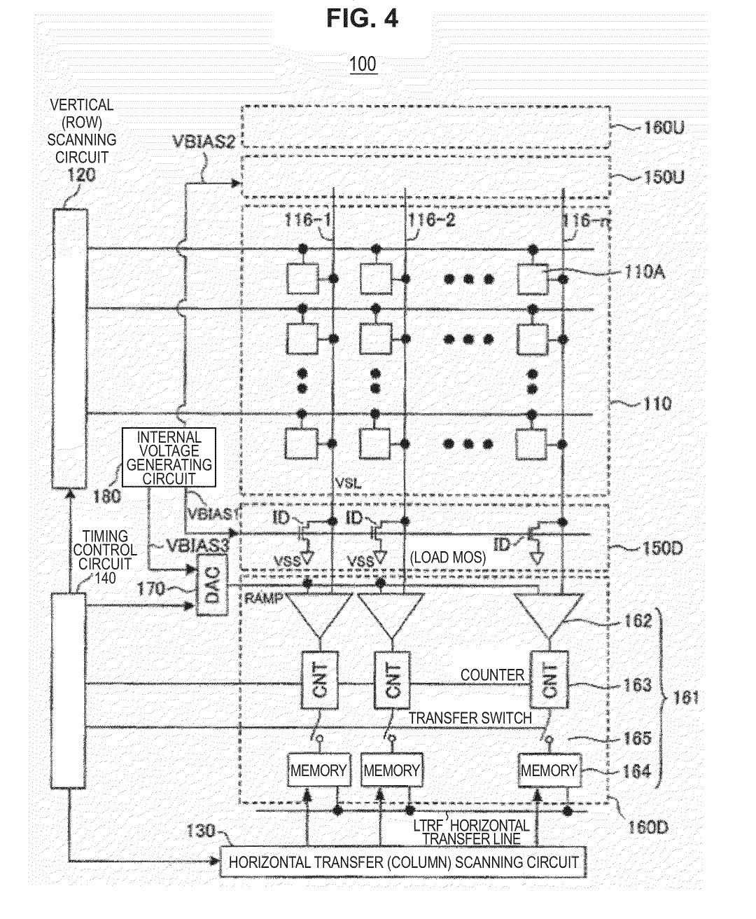

FIG. 4 is a block diagram illustrating a configuration example of a column parallel ADC-mounted solid-state image device (CMOS image sensor) according to a first embodiment.

### [Overall Configuration Example of Solid-State Image Device]

As illustrated in FIG. 4, the solid-state image device 100 has a pixel unit 110 as an imaging section, a vertical scanning circuit (row scanning circuit) 120, a horizontal transfer scanning circuit (column scanning circuit) 130, and a timing control circuit 140.

Further, the solid-state image device 100 has pixel current sources 150D and 150U as a column circuit, column parallel processing units 160D and 160U forming an ADC group, a digital-to-analog converter (DAC) 170, and an internal voltage generating circuit (bias circuit) 180.

In the present embodiment, a pixel signal readout unit is formed from the horizontal transfer scanning circuit 130, the pixel current sources 150, the column parallel processing units 160, the DAC 170 and the like. The timing control circuit 140 has a function corresponding to a control unit.

Moreover, in the present embodiment, the pixel current sources 150, the column parallel processing units 160, and the DAC 170 are configured to include a function unit for receiving supply of a bias voltage generated inside or outside.

The pixel unit 110 has a plurality of unit pixels 110A arrayed in a two dimensional configuration (a matrix configuration) made from m rows and n columns, each of the unit pixels 110A including a photodiode (photoelectric conversion element) and an amplifier inside the pixel.

### [Configuration Example of Unit Pixel]

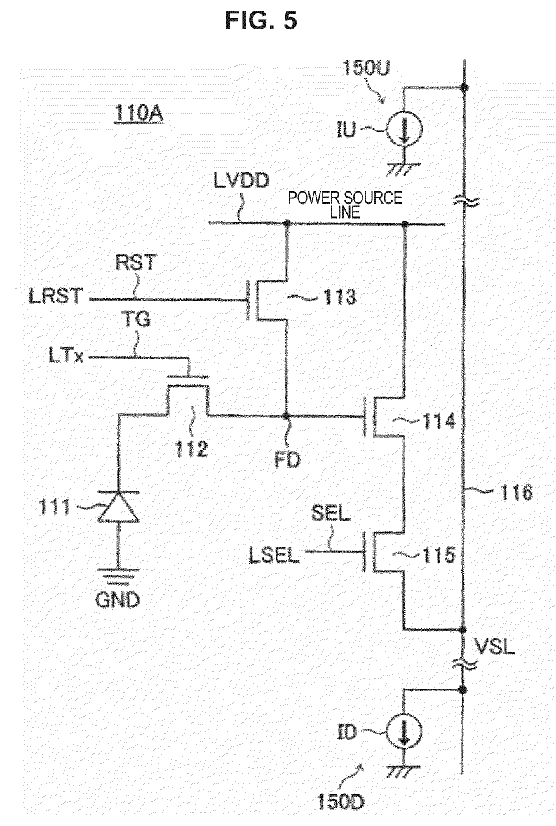

FIG. 5 illustrates one example of a pixel including four transistors in the CMOS image sensor according to the present embodiment.

The unit pixel 110A has a photodiode 111 as a photoelectric conversion element, for example.

The unit pixel 110A has four transistors as active elements for one photodiode 111, including a transfer transistor 112 as a transfer element, a reset transistor 113 as a reset element, am amplification transistor 114, and a selecting transistor 115.

The photodiode 111 photoelectrically converts incident light into electric charge (electron in this case), the amount of which corresponds to the amount of the incident light.

The transfer transistor 112 is connected to between the photodiode 111 and a floating diffusion FD used as an output node.

When a driving signal TG is provided to a gate (transfer gate) of the transfer transistor 112 through a transfer control line LTx, the transfer transistor 112 transfers the electron, which was photoelectrically converted in the photodiode 111 that is a photoelectric conversion element, to the floating diffusion FD.

The reset transistor 113 is connected to between a power source line LVDD and the floating diffusion FD.

When a reset RST is provided to a gate of the reset transistor 113 through a reset control line LRST, the reset transistor 113 resets the potential of the floating diffusion FD into the potential of the power source line LVDD.

The floating diffusion FD is connected to a gate of the amplification transistor 114. The amplification transistor 114 is connected to a vertical signal line 116 via the selecting transistor 115, and forms a source follower with constant current sources ID and IU of the pixel current sources 150D and 150U outside the pixel unit.

When a control signal (an address signal or a select signal) SEL is provided to a gate of the selecting transistor 115 through a selection control line LSEL, the selecting transistor 115 is turned on.

When the selecting transistor 115 is turned on, the amplification transistor 114 amplifies the potential of the floating diffusion FD, and outputs a voltage corresponding to the potential to the vertical signal line 116. The voltage outputted from each of the pixels through the vertical signal line 116 is outputted to the column parallel processing unit 160 that is used as a pixel signal readout circuit.

These operations are simultaneously performed on each pixel of one row in parallel since the respective gates of the transfer transistor 112, the reset transistor 113, and the selecting transistor 115 are connected in the unit of a column for example.

The reset control line LRST, the transfer control line LTx, and the selection control line LSEL which are wired to the pixel unit 110 are grouped and wired as one control line LCTL in each row in the pixel array.

These reset control line LRST, transfer control line LTx, and selection control line LSEL are driven by the vertical scanning circuit 120 that is used as a pixel driving unit.

In the solid-state image device 100, there are arranged the timing control circuit 140 which generates an internal clock as a control circuit for sequential readout of signals in the pixel unit 110, the vertical scanning circuit 120 which controls row addresses and row scanning, and the horizontal transfer scanning circuit 130 which controls column addresses and column scanning.

For example, when full-pixel readout is performed, the vertical scanning circuit 120 first performs full reset of the pixel unit 110 under the control of the timing control circuit 140.

In this case, full-screen reset is simultaneously performed when the transfer transistor 112 and the reset transistor 113 are turned on (or the reset transistor 113) is turned on.

More specifically, both (or one of) the control signal Tx which performs ON/OFF control of the transfer transistor 112 and the control signal RST which performs ON/OFF control of the reset transistor 113 are set to be active (high-level in this example).

As a consequence, the charge stored in the photodiode (photoelectric conversion element) 111 is discarded. Then, after reset is done, both the signals are switched to a low level, and the transfer transistor 112 and the reset transistor are turned off. As a consequence, the photodiode 111 converts an optical signal into charge, and the charge is stored.

Next, at the time of readout, the vertical scanning circuit 120 turns on the reset transistor 113 to reset the floating diffusion FD, and turns off the reset transistor 113. As a result, the voltage of the floating diffusion FD at this point of time is outputted through the amplification transistor 114 and the selecting transistor 115. An output at this point of time is defined as a P phase output.

Next, the transfer transistor 112 is turned on to transfer the charge stored in the photodiode 111 to the floating diffusion FD. The voltage of the floating diffusion FD at this point of time is outputted through the amplification transistor 114. An output at this point of time is defined as a D phase output.

Using a difference between the D phase output and the P phase output as an image signal makes it possible to remove from the image signal not only DC component variation in output of each pixel but also FD reset noise in the floating diffusion.

Under the control of the timing control circuit 140, the vertical scanning circuit 120 drives the pixels in each row so that pixel readout is performed alternately from the upper and lower sides of the pixel unit 110, i.e., from the rows in regions close to the pixel current sources 150U and 150D toward the center.

The timing control circuit 140 generates timing signals necessary for signal processing of the pixel unit 110, the vertical scanning circuit 120, the horizontal transfer scanning circuit 130, the column parallel processing units 160, the DAC 170, and the internal voltage generating circuit 180.

The timing control circuit 140 includes a DAC control function unit which controls generation of, for example, a reference signal RAMP (Vslop) in the DAC 170 and the internal voltage generating circuit 180.

The DAC control function unit controls so as to adjust an offset of the reference signal RAMP for each row that is AD-converted in each of the column processing circuits (ADC) 161 in the column parallel processing unit 160.

In the pixel unit 110, picture and screen images are photoelectrically converted in every pixel row through accumulation and discharge of photon with use a line shutter, and an analog signal VSL is outputted to each of the column processing circuits 161 in the column parallel processing units 160 (D, U).

In the column parallel processing units 160, each ADC block (each column unit) performs APGA-based integrated ADC and digital CDS on the analog output of the pixel unit 110 by using the reference signal (ramp signal) RAMP from the DAC 170, and outputs a digital signal of a several bits.

While the pixel current sources 150D and 150U are connected to a signal line so as to form a source follower with the amplification transistor (FD amplifier) of the pixel for pixel readout, a configuration of providing them on both ends of the signal line (upper and lower sides of the pixel unit 110) is applied to secure impedance.

A bias voltage VBAIS1 generated in the internal voltage generating circuit 180 is supplied to the pixel current source 150D.

A bias voltage VBAIS2 generated in the internal voltage generating circuit 180 is supplied to the pixel current source 150D.

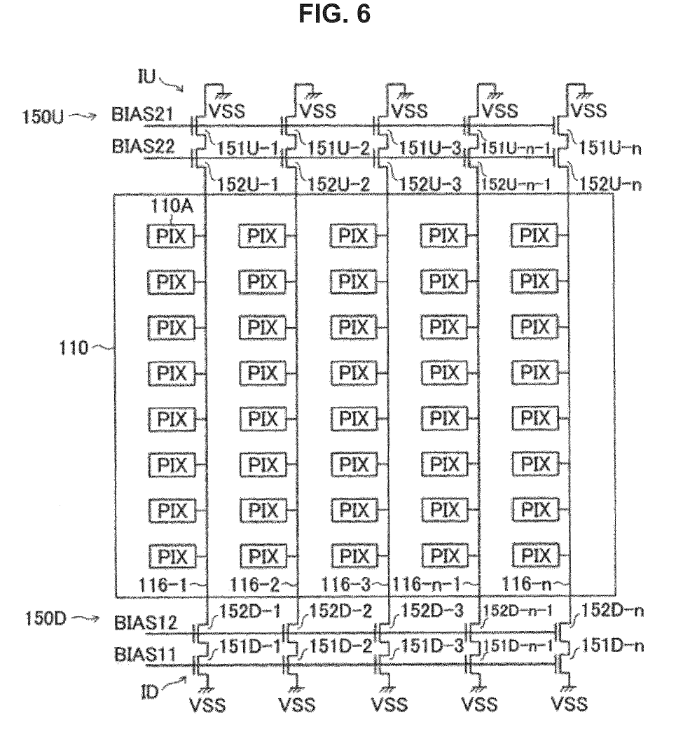

FIG. 6 illustrates a concrete configuration example of the pixel current sources arranged on both upper and lower ends of the pixel unit according to the present embodiment.

The pixel current source 150D has load MOS transistors 151D-1 to 151D-n and 152D-1 to 152D-n connected in series to between a reference potential VSS and one end (lower end) side of each of vertical signal lines 116-1 to 116-n in accordance with the column array of the pixels.

Gates of the load MOS transistors 151D-1 to 151D-n are connected in common to a supply line of a bias voltage VBIAS11 generated in the internal voltage generating circuit 180.

Gates of the load MOS transistors 152D-1 to 152D-n are connected in common to a supply line of a bias voltage VBIAS12 generated in the internal voltage generating circuit 180.

The Load MOS transistors 151D-1 to 151D-n and 152D-1 to 152D-n connected in series function as a current source ID of the source follower at the time of pixel readout.

The pixel current source 150U has load MOS transistors 151U-1 to 151U-n and 152U-1 to 152U-n connected in series to between the reference potential VSS and the other end (upper end) side of each of the vertical signal lines 116-1 to 116-n in accordance with the column array of the pixels.

Gates of the load MOS transistors 151U-1 to 151U-n are connected in common to a supply line of a bias voltage VBIAS21 generated in the internal voltage generating circuit 180.

Gates of the load MOS transistors 152U-1 to 152U-n are connected in common to a supply line of a bias voltage VBIAS22 generated in the internal voltage generating circuit 180.

The Load MOS transistors 151U-1 to 151U-n and 152U-1 to 152U-n connected in series function as a current source IU of the source follower at the time of pixel readout.

### [Configuration Example of Column ADC]

The column parallel processing units 160D and 160U of the present embodiment have the same configuration, in which a plurality of column processing circuits (ADCs) 161 that form the ADC blocks are arrayed.

More specifically, each of the column parallel processing units 160 (D, U) has k-bit digital signal conversion function, and is arranged in each of the vertical signal lines (column lines) 116-1 to 116-n so as to form column parallel ADC blocks.

Each of the ADCs 161 has a comparator 162 as a function unit which compares the reference signal RAMP (Vslop), formed by changing a reference signal generated by the DAC 170 into a stair-like ramp waveform, with the analog signal VSL obtained from the pixels in each row line via the vertical signal line.

Further, each of the ADCs has a counter 163 which counts comparison time and a memory (latch) 164 which retains a counted result of the counter 163. The ADC 161 has a transfer switch 165.

For example, the output of each of the memories 164 is connected to a horizontal transfer line LTRF with a k bit width.

Corresponding to the horizontal transfer line LTRF, k amplification circuits and signal processing circuits are arranged.

In the column parallel processing unit 160 having such comparators, the analog signal potential VSL read into the vertical signal line 116 is compared with the reference signal RAMP in the comparator 162 arranged in every column (every column).

At this time, the counters 163 which are arranged in every column like the comparators 162 operate.

Each of the ADCs 161 converts the potential (analog signal) VSL of the vertical signal line 116 into a digital signal by change in a reference signal RAMP (potential Vslop) having a ramp waveform and a counter value which have one-to-one correspondence.

The ADC 161 converts a change in voltage of the reference signal RAMP (potential Vslop) into a change in time. By counting the time in a certain cycle (clock), the change is converted into a digital value.

When the analog signal VSL and the reference signal RAMP (Vslop) intersect, the output of the comparator 162 is inverted, and an input clock of the counter 163 is stopped, or the stopped clock is inputted into the counter 63 to complete AD conversion. AD-converted data is retained in the memory 164.

After the end of the above-stated AD conversion period, the data retained in the memory 164 is transferred to the horizontal transfer line LTRF by the horizontal transfer scanning circuit 130. The data is then inputted into the signal processing circuit through an amplification circuit and is subjected to specified signal processing to generate a two-dimensional image.

In the horizontal transfer scanning circuit 130, several channels are simultaneously used in parallel to transfer data so as to secure a transfer rate.

The timing control circuit 140 generates timings necessary for signal processing in respective blocks such as the pixel unit 110 and the column parallel processing unit 160.

Downstream signal processing circuits use signals stored in a line memory to perform correction of vertical line defects and/or point defects, clamping processing of signals, and digital signal processing including parallel/serial conversion, compression, encoding, adding, averaging, and sampling operations.

In the solid-state image device 100 of the present embodiment, the digital output of the signal processing circuit is transmitted as the input of ISP or baseband LSI.

Under the control of the timing control circuit 140, the DAC 170 generates a reference signal (ramp signal) with a slope waveform that changes to a linear form having a certain inclination and supplies it to the column parallel processing unit 160.

For example, under the control of the timing control circuit 140, the DAC 170 generates a reference signal RAMP with an adjusted offset for each column that is subjected to AD conversion by each column processing circuit (ADCs) 161 in the column parallel processing unit 160.

The internal voltage generating circuit 180 generates bias voltage VBIAS1 (11, 12) and VBIAS2 (21, 22), and supplies them to the pixel current sources 150D and 150U.

The internal voltage generating circuit 180 generates a bias voltage VBIAS3, and supplies it to a current source for current control (such as the gate of a transistor) of the DAC 170.

### [Operation Example of Full-Pixel Readout in Solid-State Image Device]

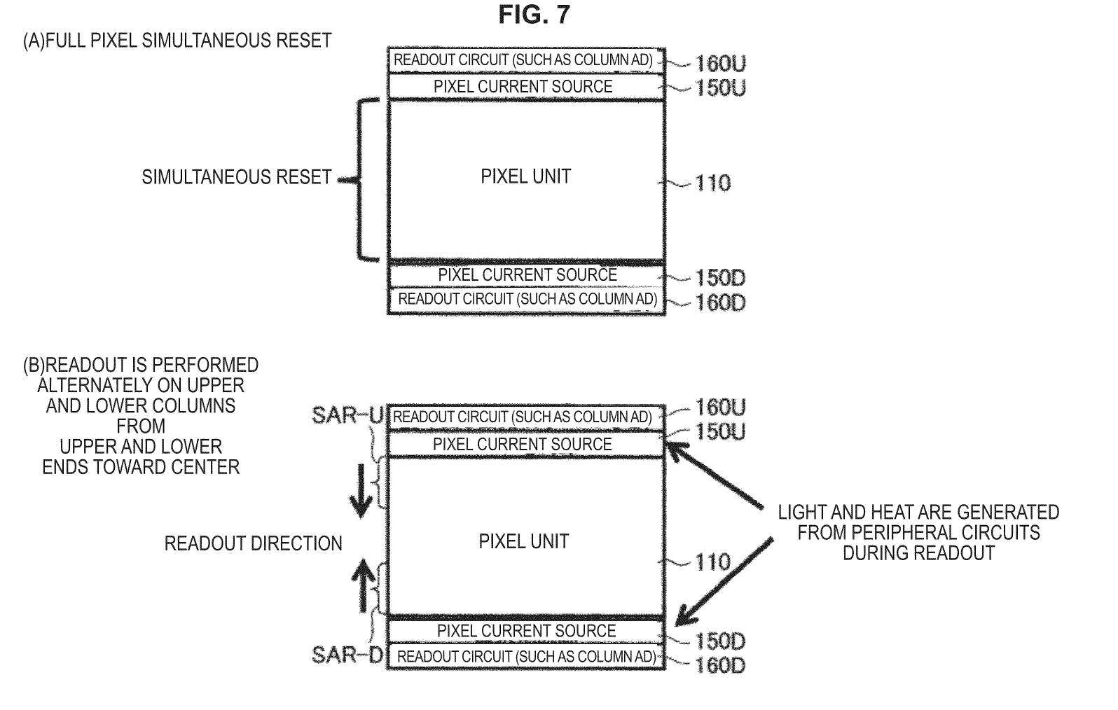

FIGS. 7(A) and 7(B) are explanatory views illustrating an operation example of full-pixel readout in the solid-state image device according to the present embodiment.

Now, the operation according to the above configuration is described with reference to FIG. 7.

For example, when full-pixel readout is performed under the control of the timing control circuit 140, full reset of the pixel unit 110 is first performed as illustrated in FIG. 7(A).

In this case, full-screen reset is simultaneously performed when the transfer transistor 112 and the reset transistor 113 are turned on to be turned on.

More specifically, the vertical scanning circuit 120 sets both the control signal Tx which performs ON/OFF control of the transfer transistor 112 and the control signal RST which performs ON/OFF control of the reset transistor 113 to be active or a high-level.

As a consequence, the charge stored in the photodiode 111 is discarded.

Then, after reset is done, both the signals are switched to a low level, and the transfer transistor 112 and the reset transistor are turned off. As a consequence, the photodiode 111 converts an optical signal into charge, and the charge is stored.

Next, pixel readout is performed.

During the read operation, light and heat is generated from the peripheral circuits, the pixel current sources 150D and 150U in particular.

Accordingly, when the pixel unit 110 is read out in order from the lower end to the upper end, the locations closer to the upper end have longer charge storage time.

Since a portion close to the peripheral circuit of the upper end receives the influence of the light and heat generated from the peripheral circuit for a long period of time, the portion causes whitening with a shading pattern.

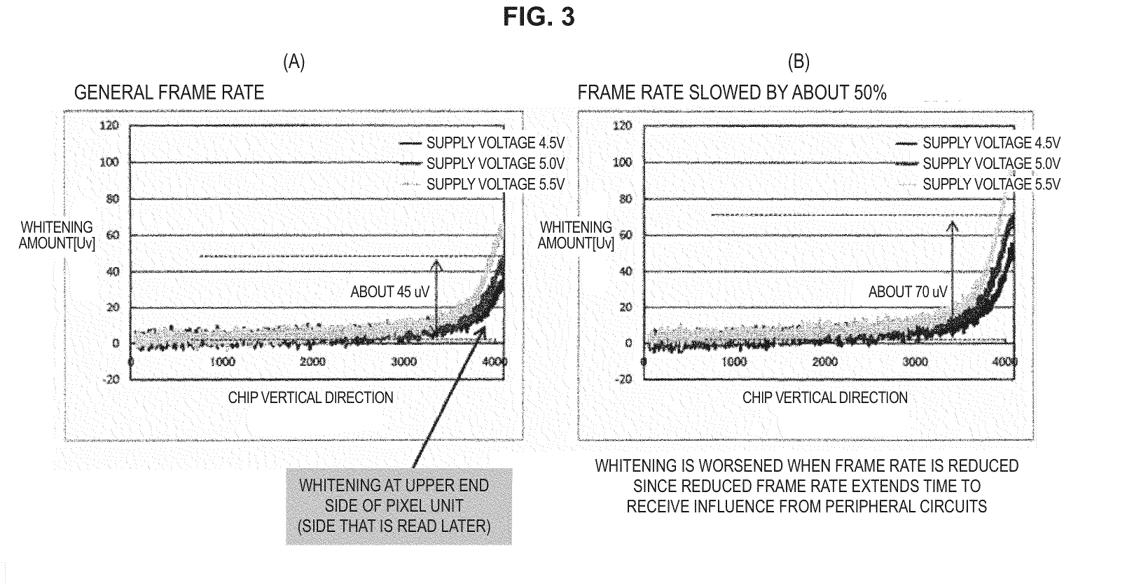

From the perspective of the example in FIG. 3, it can be presumed that whitening tends to occur in each of regions that occupy about ⅕ of the full screen from the end of the screen.

Accordingly, in the present embodiment, as illustrated in FIG. 7(B), the pixels in each row are driven so that pixel readout is performed alternately from the upper and lower sides of the pixel unit 110, i.e., from the rows in regions close to the pixel current sources 150U and 150D, toward the center.

For example, when the pixel unit 110 has 5000 rows in a vertical (V) direction, readout is performed in the order shown below.

Note that, in this example, it is assumed that the 1st row is a row close to the pixel current source 150D at the lower end side, and the 5000th row is a row close to the pixel current source 150U at the upper end side. However, this order may be reversed.

### [First Example of Pixel Readout Order]

In the first example, readout is performed in the following order.

Example 1) in the order of 1st row, 5000th row, 2nd row, 4999th row, 3rd row, 4998th row, . . . 2500th row, 2501st row (R row->B row->B row->R row)

In the first example, the pixels of each row are driven so that readout is performed one row at a time, alternately from the rows in the regions close to the pixel current sources 150U and 150D, toward the center.

In the first example, since the upper and lower ends of the screen are read out first, the storage time of these portions is substantially shortened. As a consequence, whitening at the end of the screen due to the influence of the peripheral circuits, the pixel current sources in particular, can be suppressed.

### [Second Example of Pixel Readout Order]

In the second example, readout is performed in the following order.

Example 2) in the order of 1st row, 2nd row, 4999th row, 5000th row, 3rd row, 4th row, . . . 2501st row, 2502nd row (R row->B row->R row->B row)

In the second example, the pixels of each row are driven so that readout is performed two rows at a time, alternately from the rows in the regions close to the pixel current sources 150U and 150D, toward the center.

In the second example, since the upper and lower ends of the screen are also read out first, the storage time of these portions is substantially shortened. As a consequence, whitening at the end of the screen due to the influence of the peripheral circuits, the pixel current sources in particular, can be suppressed.

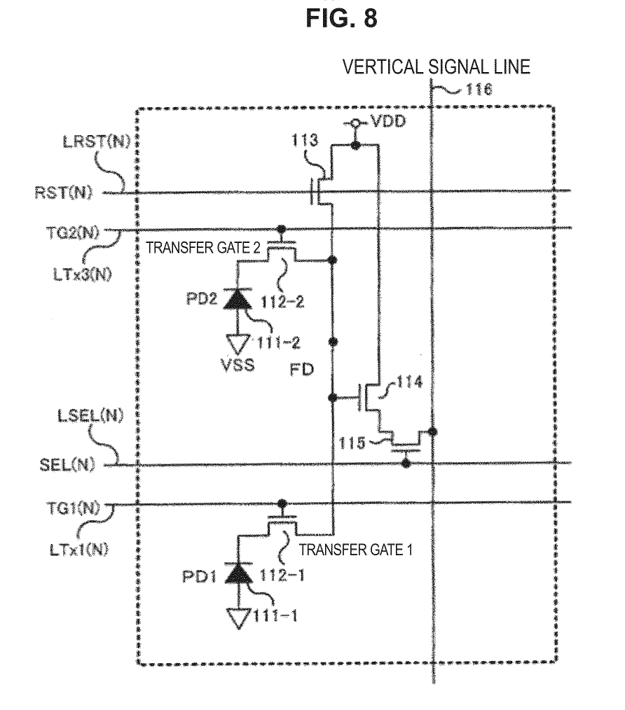

The method for reading the pixels two rows at a time alternately from the upper and lower sides as in the second example is applicable to a solid-state image device which employs two-pixel sharing configuration as illustrated in FIG. 8.

More specifically, successive readout of the rows, the number of which is equal to the number of sharing pixels, is performed, and the successive readout is performed alternately from the upper and lower sides. This makes it possible to perform the full-pixel readout suitable for the pixel sharing configuration.

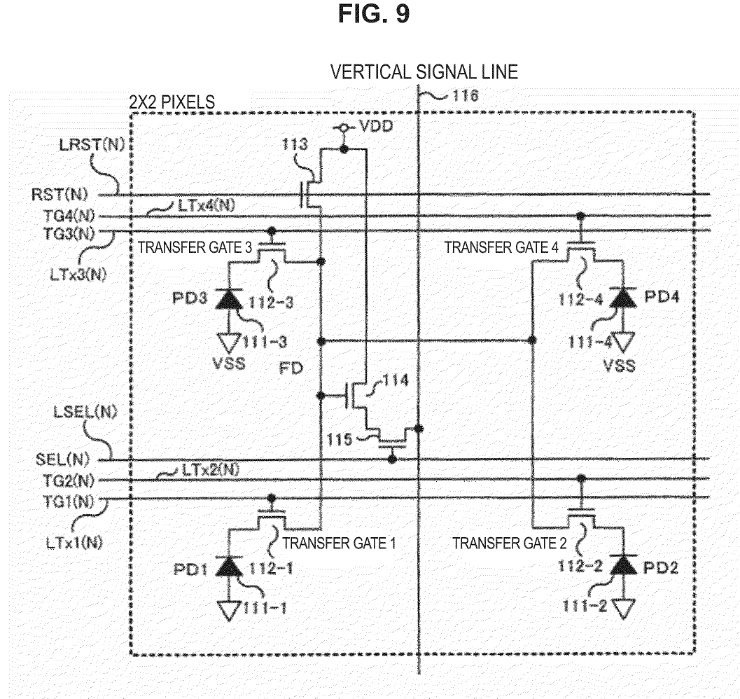

It is to be noted that, in the case of four-pixel sharing as illustrated in FIG. 9, readout is performed in the following order.

Example 3) in the order of 1st row, 2nd row, 3rd row, 4th row, 4997th row, 4998th row, 4999th row, 5000th row, 5th row, 6th row, 7th row, 8th row, . . . 2501st row, 2502nd row, 2503rd row, 2503rd row (R row->B row->R row->B row).

It is not necessarily needed to alternately read the pixels with regularity as in the above examples.

For example, specific regions SAR-D and SAR-U including the number of rows, or the number of rows set to include a margin, from the upper and lower ends of the screen where whitening is predicted to appear due to the influence of the peripheral circuits, are alternately read out first.

After that, readout is performed in order from the row adjacent to one specific region toward the row adjacent to the other specific region, or the readout is performed in order from the row adjacent to one specific region toward the row positioned in the center and then from the row adjacent to the other specific region toward the row adjacent to the read central row.

In other words, the specific regions including the number of rows, or the number of rows set to include a margin, from the upper and lower ends of the screen where whitening is predicted to appear due to the influence of the peripheral circuits, are alternately read out first, and then the readout may be performed in arbitrary order.

Concrete operation at the time of readout will be described below.

At the time of readout, the vertical scanning circuit 120 turns on the reset transistor 113 to reset the floating diffusion FD, and turns off the reset transistor 113. As a result, the voltage of the floating diffusion FD at this point of time is outputted through the amplification transistor 114 and the selecting transistor 115. An output at this point of time is defined as a P phase output.

Next, the transfer transistor 112 is turned on to transfer the charge stored in the photodiode 111 to the floating diffusion FD. The voltage of the floating diffusion FD at this point of time is outputted through the amplification transistor 114. An output at this point of time is defined as a D phase output.

A signal read from each pixel is inputted into each of the column processing circuits (ADCs) 161.

In each of the column processing circuits (ADCs) 161, an analog signal potential VSL read out into the vertical signal line 116 is compared with a reference signal RAMP in the comparator 162 arranged in every column.

The counter 163 executes counting until the level of the analog potential VSL intersects the level of the reference signal RAMP and thereby the output of the comparator 162 is inverted.

For example, the counter 163 executes count operation in synchronization with a clock CLK. Once the output level of the comparator 162 is inverted, the count operation is stopped and a value at that time is retained in the memory 164.

This P-phase reset level varies by pixel.

In the second round, a signal photoelectrically converted in each of the unit pixels 110A is read out into the vertical signal line 116 (-1 to -n) (D phase), and AD conversion is executed.

In each of the column processing circuits (ADCs) 161, an analog signal potential VSL read out into the vertical signal line 116 is compared with a reference signal RAMP in the comparator 162 arranged in every column.

The counter 163 executes counting until the level of the analog potential VSL intersects the level of the reference signal RAMP and thereby the output of the comparator 162 is inverted.

For example, the counter 163 executes count operation in synchronization with a clock CLK. Once the output level of the comparator 162 is inverted, the count operation is stopped and a value at that time is retained in the memory 164.

Then, calculation of (D phase level−P phase level) in combination with the result of P phase and D phase conversion can implement correlated double sampling (CDS).

Signals converted into digital signals are read one by one into the amplification circuits by the horizontal (column) transfer scanning circuit 130 via the horizontal transfer line LTRF, and are outputted in the end.

This is how the column parallel output processing is performed.

As described in the foregoing, according to the solid-state image device of the present embodiment, the upper and lower ends of the screen are read out first, so that the storage time in these portions is substantially shortened. As a result, whitening at the end of the screen due to the influence of the peripheral circuits can be suppressed.

### 2. Second Embodiment

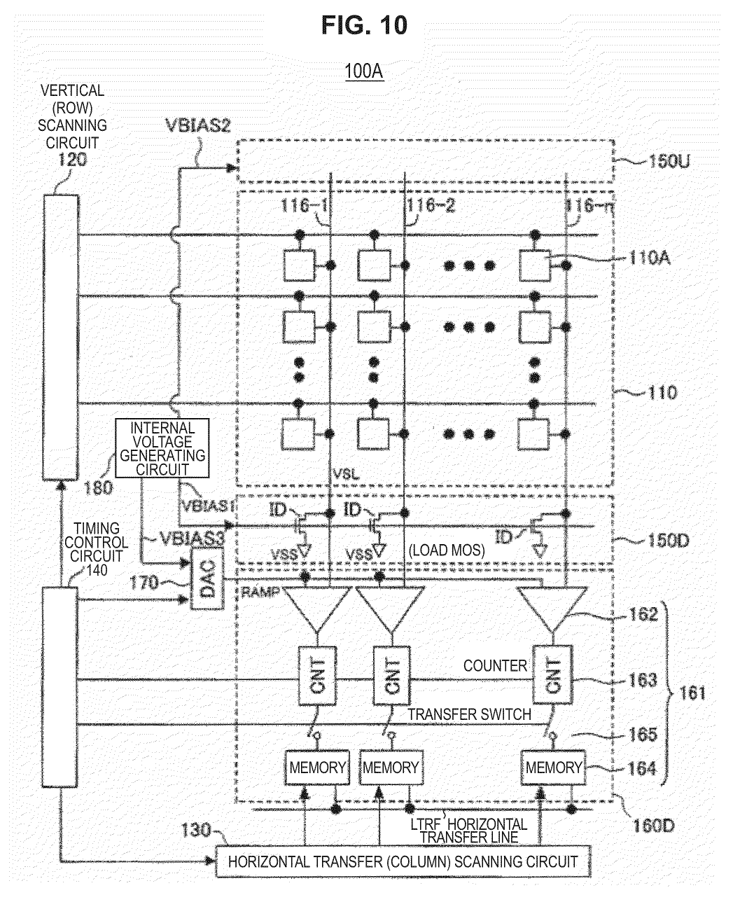

FIG. 10 is a block diagram illustrating a configuration example of a column parallel ADC-mounted solid-state image device (CMOS image sensor) according to a second embodiment.

A solid-state image device 100A according to the second embodiment is different from the solid-state image device 100 according to the first embodiment in the point that the column parallel processing unit 160 as a readout circuit (such as column ADCs) is arranged only at one side.

In this case, since the pixel current sources are also provided on the upper and lower sides, the full-pixel readout method disclosed in the first embodiment may be applied.

According to the second embodiment, the effects same as the aforementioned first embodiment can be achieved.

### 3. Third Embodiment

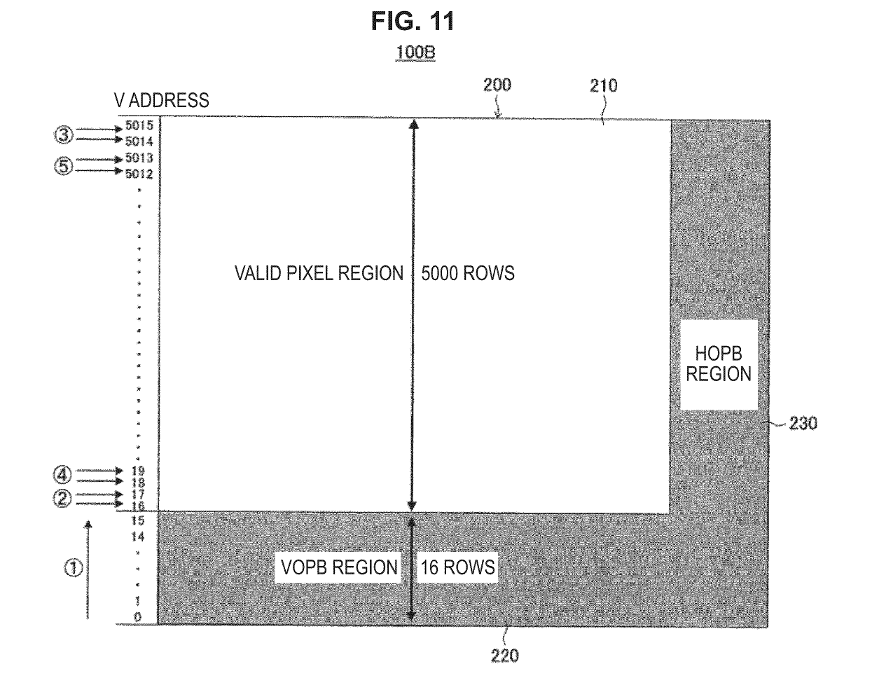

FIG. 11 illustrates configuration of a pixel unit in a column parallel ADC-mounted solid-state image device (CMOS image sensor) according to a third embodiment.

In a solid-state image device 100B according to the second embodiment, a pixel unit 200 has vertical (V) and horizontal (H) optical black (OBP) regions 220 and 230 formed in a light shielding state on the lower end side and right end side of a valid pixel region 210.

In this example, the VOPB region 220 includes 16 rows from the 0th to 15th rows, while the valid pixel region 210 includes 5000 rows from No. 16 to the 5015th row.

In the solid-state image device 100B, the full-pixel readout is performed such that 16 rows of the VOPB region 220 are read out in sequence first, and then readout of the valid pixel region 210 is performed. The readout methods of the first, second and third examples described in the first embodiment are applied to this readout.

When the second example is applied, readout is performed in the following order.

Example 2) in the order of 16th row, 17th row, 5014th row, 5015th row, 18th row, 19th row, . . . 25016th row, 25017th row (R row->B row->R row->B row)

When the readout method of the second example is applied in this way, the pixels of each row are driven so that readout is performed alternately from the rows in the regions close to the pixel current sources 150U and 150D two row at a time toward the center.

In the third embodiment, since the upper and lower ends of the screen are read out first, the storage time of these portions is substantially shortened. As a consequence, whitening at the end of the screen due to the influence of the peripheral circuits, the pixel current sources in particular, can be suppressed.

The solid-state image device having such effects is applicable as an imaging device for digital cameras and/or video cameras.

### 4. Fourth Embodiment

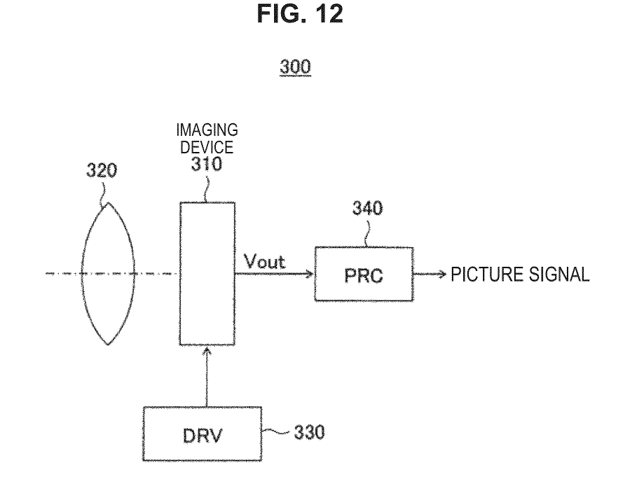

FIG. 12 illustrates one configuration example of a camera system to which the solid-state image device according to the embodiments of the present invention is applied.

A camera system 300 has an imaging device 310 to which the solid-state image devices 100, 100A and 100B according to the embodiments can be applied as illustrated in FIG. 12.

For example, the camera system 300 has a lens 320 which forms an image of incident light (image light) on an imaging surface as an optical system which guides incident light to (which forms an object image on) a pixel region of the imaging device 310.

Further, the camera system 300 has a drive circuit (DRV) 330 which drives the imaging device 310, and a signal processing circuit (PRC) 340 which processes an output signal of the imaging device 310.

The drive circuit 330 has a timing generator (not illustrated) which generates various kinds of timing signals including a start pulse and a clock pulse which drive circuits in the imaging device 310, and drives the imaging device 310 with specified timing signals.

The signal processing circuit 340 also performs specified signal processing on an output signal of the imaging device 310.

An image signal processed in the signal processing circuit 340 is recorded, for example, on a record medium such as a memory. Image information recorded on the recording medium is printed with a printer and the like to produce hard copy. The image signal processed in the signal processing circuit 340 is projected as a moving image on a monitor which is made of a liquid crystal display and the like.

As described in the foregoing, a high-accuracy camera can be implemented by mounting the solid-state image devices 100, 100A and 100B as an imaging device 310 on imaging apparatuses such as digital still cameras.

Additionally, the present technology may also be configured as below.

(1)

A solid-state image device including:

a pixel unit adapted to have a plurality of pixels arrayed in a matrix form, the plurality of pixels including a photoelectric conversion element which converts an optical signal into an electrical signal and stores signal charge corresponding to exposure time;

peripheral circuits adapted to be arranged adjacent to edge portions of the pixel unit that face each other and adapted to be driven in association with at least read operation of a pixel signal; and

a pixel signal readout unit adapted to read the pixel signal from the pixel unit in a unit of a plurality of pixels, wherein

when full-pixel readout is performed, the pixel signal readout unit resets all the pixels, and then performs pixel readout at least row by row alternately from at least rows in specific regions close to the peripheral circuits arranged beside the edge portions of the pixel unit that face each other.

(2)

The solid-state image device according to (1), wherein

when the full-pixel readout is performed, the pixel signal readout unit resets all the pixels, then performs readout at least row by row alternately from the rows in regions close to the peripheral circuits arranged beside the edge portions of the pixel unit that face each other, and performs readout of a central region between the edge portions of the pixel unit excluding the specific regions.

(3)

The solid-state image device according to (1) or (2), wherein

when the full-pixel readout is performed, the pixel signal readout unit resets all the pixels, and then performs readout at least row by row alternately from the rows in regions close to the peripheral circuits arranged beside the edge portions of the pixel unit that face each other toward a central portion between the edge portions of the pixel unit.

(4)

The solid-state image device according to any one of (1) to (3), wherein

the pixel unit includes sharing pixels to share an output node among the plurality of pixels in a manner that a pixel signal of each pixel in the sharing pixels are capable of being selectively outputted from the shared output node to the corresponding pixel signal readout line, and

the pixel signal readout unit performs successive readout of the rows which are equal to the sharing pixels in number, and the successive readout is alternately performed.

(5)

The solid-state image device according to any one of (1) to (4), wherein

the pixel unit includes a valid pixel region, and an optical black region which is in a light shielding state beside the peripheral circuits in a region other than the valid pixel region, and

when the full-pixel readout is performed, the pixel signal readout unit resets all the pixels, then performs readout of the optical black region in order, and performs pixel readout in the valid pixel region at least row by row alternately from at least the rows in the specific regions close to the peripheral circuits arranged beside the edge portions of the pixel unit that face each other.

(6)

The solid-state image device according to any one of (1) to (4), including:

a pixel signal readout line, wherein

the pixel signal readout unit reads out the pixel signal from the pixel unit through the pixel signal readout line, and

the peripheral circuits arranged beside the edge portions of the pixel unit that face each other include a load element which functions as a current source connected to the pixel signal readout line and through which a current corresponding to a bias voltage is applied.

(7)

A method for driving a solid-state image device including peripheral circuits adapted to be arranged adjacent to edge portions that face each other and adapted to be driven in association with at least read operation of a pixel signal, and a pixel unit adapted to have a plurality of pixels arrayed in a matrix form, the plurality of pixels including a photoelectric conversion element which converts an optical signal into an electrical signal and stores signal charge corresponding to exposure time, the method including, when full-pixel readout is performed on the pixel unit:

a resetting step of resetting all the pixels; and

a readout step of performing pixel readout at least row by row alternately from at least rows in specific regions close to the peripheral circuits arranged beside the edge portions of the pixel unit that face each other.

(8)

The method for driving a solid-state image device according to (7), wherein

in the readout step, when the full-pixel readout is performed, all the pixels are reset, then readout is performed at least row by row alternately from the rows in regions close to the peripheral circuits arranged beside the edge portions of the pixel unit that face each other, and readout of a center region between the edge portions of the pixel unit excluding the specific regions is performed.

(9)

The method for driving a solid-state image device according to (7) or (8), wherein

in the readout step, when the full-pixel readout is performed, all the pixels are reset, and then readout is performed at least row by row alternately from the rows in the regions close to the peripheral circuits arranged beside the edge portions of the pixel unit that face each other toward a central portion between the edge portions of the pixel unit.

(10)

The method for driving a solid-state image device according to any one of (7) to (9), wherein

the pixel unit includes sharing pixels to share an output node among the plurality of pixels in a manner that a pixel signal of each pixel in the sharing pixels are capable of being selectively outputted from the shared output node to the corresponding pixel signal readout line, and

in the readout step, successive readout of the rows which is equal to the sharing pixels in number is performed and the successive readout is alternately performed.

(11)

The method for driving a solid-state image device according to any one of (7) to (10), wherein

the pixel unit includes a valid pixel region, and an optical black region which is in a light shielding state beside the peripheral circuits in a region other than the valid pixel region,

in the readout step, when the full-pixel readout is performed, all the pixels are reset, and then readout of the optical black region is performed in order, and

pixel readout in the valid pixel region is performed at least row by row alternately from at least the rows in the specific regions close to the peripheral circuits arranged beside the edge portions of the pixel unit that face each other.

(12)

A camera system including:

a solid-state image device; and

an optical system adapted to form an object image on the solid-state image device, wherein

the solid-state image device includes
a pixel unit adapted to have a plurality of pixels arrayed in a matrix form, the plurality of pixels including a photoelectric conversion element which converts an optical signal into an electrical signal and stores signal charge corresponding to exposure time,
peripheral circuits adapted to be arranged adjacent to edge portions of the pixel unit that face each other and adapted to be driven in association with at least read operation of a pixel signal, and
a pixel signal readout unit adapted to read the pixel signal from the pixel unit in a unit of a plurality of pixels, and

when full-pixel readout is performed, the pixel signal readout unit resets all the pixels, and then performs pixel readout at least row by row alternately from at least rows in specific regions close to the peripheral circuits arranged beside the edge portions of the pixel unit that face each other.

### REFERENCE SIGNS LIST

100, 100A, 100B solid-state image device
110 pixel unit
120 vertical scanning circuit
130 horizontal transfer scanning circuit
140 timing control circuit
150 load circuit
160 column parallel processing unit
161 column processing circuit (ADC)
162 comparator
163 counter
164 memory
170 DAC
180 internal voltage generating circuit
LTRF horizontal transfer line
200 pixel unit
210 valid pixel region
220 vertical optical black region (VOPB)
230 horizontal optical black region (HOPB)
SAR-D, SAR-U specific region
300 camera system
310 imaging device
320 lens
330 drive circuit
340 signal processing circuit

1. A solid-state image device comprising:
a pixel unit adapted to have a plurality of pixels arrayed in a matrix form, the plurality of pixels including a photoelectric conversion element which converts an optical signal into an electrical signal and stores signal charge corresponding to exposure time;
peripheral circuits adapted to be arranged adjacent to edge portions of the pixel unit that face each other and adapted to be driven in association with at least read operation of a pixel signal; and
a pixel signal readout unit adapted to read the pixel signal from the pixel unit in a unit of a plurality of pixels, wherein
when full-pixel readout is performed, the pixel signal readout unit resets all the pixels, and then performs pixel readout at least row by row alternately from at least rows in specific regions close to the peripheral circuits arranged beside the edge portions of the pixel unit that face each other.

2. The solid-state image device according to claim 1, wherein
when the full-pixel readout is performed, the pixel signal readout unit resets all the pixels, then performs readout at least row by row alternately from the rows in regions close to the peripheral circuits arranged beside the edge portions of the pixel unit that face each other, and performs readout of a central region between the edge portions of the pixel unit excluding the specific regions.

3. The solid-state image device according to claim 1, wherein
when the full-pixel readout is performed, the pixel signal readout unit resets all the pixels, and then performs readout at least row by row alternately from the rows in regions close to the peripheral circuits arranged beside the edge portions of the pixel unit that face each other toward a central portion between the edge portions of the pixel unit.

4. The solid-state image device according to claim 1, wherein
the pixel unit includes sharing pixels to share an output node among the plurality of pixels in a manner that a pixel signal of each pixel in the sharing pixels are capable of being selectively outputted from the shared output node to the corresponding pixel signal readout line, and
the pixel signal readout unit performs successive readout of the rows which are equal to the sharing pixels in number, and the successive readout is alternately performed.

5. The solid-state image device according to claim 1, wherein
the pixel unit includes a valid pixel region, and an optical black region which is in a light shielding state beside the peripheral circuits in a region other than the valid pixel region, and
when the full-pixel readout is performed, the pixel signal readout unit resets all the pixels, then performs readout of the optical black region in order, and performs pixel readout in the valid pixel region at least row by row alternately from at least the rows in the specific regions close to the peripheral circuits arranged beside the edge portions of the pixel unit that face each other.

6. The solid-state image device according to claim 1, comprising:
a pixel signal readout line, wherein
the pixel signal readout unit reads out the pixel signal from the pixel unit through the pixel signal readout line, and
the peripheral circuits arranged beside the edge portions of the pixel unit that face each other include a load element which functions as a current source connected to the pixel signal readout line and through which a current corresponding to a bias voltage is applied.

7. A method for driving a solid-state image device including peripheral circuits adapted to be arranged adjacent to edge portions that face each other and adapted to be driven in association with at least read operation of a pixel signal, and a pixel unit adapted to have a plurality of pixels arrayed in a matrix form, the plurality of pixels including a photoelectric conversion element which converts an optical signal into an electrical signal and stores signal charge corresponding to exposure time, the method comprising, when full-pixel readout is performed on the pixel unit:
a resetting step of resetting all the pixels; and
a readout step of performing pixel readout at least row by row alternately from at least rows in specific regions close to the peripheral circuits arranged beside the edge portions of the pixel unit that face each other.

8. The method for driving a solid-state image device according to claim 7, wherein
in the readout step, when the full-pixel readout is performed, all the pixels are reset, then readout is performed at least row by row alternately from the rows in regions close to the peripheral circuits arranged beside the edge portions of the pixel unit that face each other, and readout of a center region between the edge portions of the pixel unit excluding the specific regions is performed.

9. The method for driving a solid-state image device according to claim 7, wherein
in the readout step, when the full-pixel readout is performed, all the pixels are reset, and then readout is performed at least row by row alternately from the rows in the regions close to the peripheral circuits arranged beside the edge portions of the pixel unit that face each other toward a central portion between the edge portions of the pixel unit.

10. The method for driving a solid-state image device according to claim 7, wherein
the pixel unit includes sharing pixels to share an output node among the plurality of pixels in a manner that a pixel signal of each pixel in the sharing pixels are capable of being selectively outputted from the shared output node to the corresponding pixel signal readout line, and
in the readout step, successive readout of the rows which is equal to the sharing pixels in number is performed and the successive readout is alternately performed.

11. The method for driving a solid-state image device according to claim 7, wherein
the pixel unit includes a valid pixel region, and an optical black region which is in a light shielding state beside the peripheral circuits in a region other than the valid pixel region,
in the readout step, when the full-pixel readout is performed, all the pixels are reset, and then readout of the optical black region is performed in order, and
pixel readout in the valid pixel region is performed at least row by row alternately from at least the rows in the specific regions close to the peripheral circuits arranged beside the edge portions of the pixel unit that face each other.

12. A camera system comprising:
a solid-state image device; and
an optical system adapted to form an object image on the solid-state image device, wherein
the solid-state image device includes
a pixel unit adapted to have a plurality of pixels arrayed in a matrix form, the plurality of pixels including a photoelectric conversion element which converts an optical signal into an electrical signal and stores signal charge corresponding to exposure time,
peripheral circuits adapted to be arranged adjacent to edge portions of the pixel unit that face each other and adapted to be driven in association with at least read operation of a pixel signal, and
a pixel signal readout unit adapted to read the pixel signal from the pixel unit in a unit of a plurality of pixels, and
when full-pixel readout is performed, the pixel signal readout unit resets all the pixels, and then performs pixel readout at least row by row alternately from at least rows in specific regions close to the peripheral circuits arranged beside the edge portions of the pixel unit that face each other.
